(19) United States
(12) Patent Application Publication
(10) Pub. No.: US 2005/0214195 A1
(43) Pub. Date: Sep. 29, 2005

(54) Method for manufacturing a carbon nanotube multilayer pattern using photolithography and dry etching

(76) Inventors: Hee Tae Jung, Daejeon (KR); Do Hyun Kim, Daejeon (KR); Do Hwan Choi, Seoul (KR); Dae Hwan Jung, Daejeon (KR); Jae Shin Lee, Daejeon (KR)

Correspondence Address: INTELLECTUAL PROPERTY / TECHNOLOGY LAW, PO BOX 14329, RESEARCH TRIANGLE PARK, NC, 27709, US

(21) Appl. No.: 10/962,363

(22) Filed: Oct. 8, 2004

(30) Foreign Application Priority Data
Mar. 27, 2004 (KR) 10-2004-0021031

(51) Int. Cl. H01L 21/00

(52) U.S. Cl. 423/445 B

(57) ABSTRACT

A method for forming CNT multilayer film patterns, which comprises repeatedly attaching CNTs having exposed carboxyl groups onto a substrate having exposed amine groups by amide linkage, so as to form a CNT multilayer film, and then forming CNT multilayer film patterns from the CNT multilayer film by photolithography and dry etching. Also disclosed is a method for fabricating CNT multilayer film patterns where a variety of chemical functional groups are exposed, by thermally treating CNT multilayer film patterns obtained as provided in the preceding sentence, to obtain CNT multilayer film patterns devoid of surface defect sites, followed by physically attaching either surfactants or chemical substances having sites capable of π-stacking, to the CNT multilayer film patterns devoid of defect sites. Such methodology allows fabrication of clear CNT multilayer film patterns in which CNTs are attached only at selected regions, resolving prior art issues of CNTs being attached also at non-selected regions. CNT multilayer film patterns having chemical functional groups physically attached thereto and exposed to the surface, are useful in the fabrication of biosensors.

### CROSS-REFERENCE TO RELATED APPLICATION

This application claims priority under 35 USC 119 of Korean Patent Application No. 10-2004-0021031 filed Mar. 27, 2004

### BACKGROUND OF THE INVENTION

1. Field of the Invention

The present invention relates to a method for forming multilayer film patterns of carbon nanotubes (CNTs), the method comprising repeatedly attaching CNTs having exposed carboxyl groups onto a substrate having exposed amine groups by amide linkage so as to form a CNT multilayer film, and then subjecting the CNT multilayer film to photolithography and dry etching. The present invention also relates to a method for fabricating CNT multilayer film patterns where a variety of chemical functional groups are exposed, the method comprising thermally treating the CNT multilayer film patterns obtained by the method mentioned in the preceding sentence, so as to obtain CNT multilayer film patterns having no defect site on the surface, and then physically attaching either surfactants or chemical substances having sites capable of π-stacking, to the CNT multilayer film patterns having no defect sites.

2. Background of the Related Art

Carbon nanotube (CNT) is an allotrope of carbon, which exists abundantly on the earth. CNTs are tubular materials in which a carbon atom is connected to other carbons in the form of a hexagonal honeycomb structure. Their diameter is about the size of one nanometer (1/10⁹ meter). CNT is known to have excellent mechanical properties, electrical selectivity, field emission properties and highly efficient hydrogen storage properties and is among the most defect-free of all existing materials.

Because of their properties of excellent structural rigidity, chemical stability, ability to act as ideal one-dimensional (1D) “quantum wires” with either semiconducting or metallic behaviors and a large aspect ratio, CNT exhibits a broad range of potential applications as a basic material of flat panel displays, transistors, energy reservoirs, etc., and as various sensors with nanosize (Dai, H., Acc. Chem. Res., 35:1035, 2002).

As common technologies forming the basis of the development of various industry fields and product fields together with CNTs, ultra-LSI and various thin film devices are being developed at a surprising rate. In ultra-LSI as an example, the motivation for development includes the development of film growth and ion implantation technologies, and the development of microprocessing technology using exposure and dry etching. Meanwhile, etching technology has changed from the wet etching technology of etching substrates or thin films using acidic or alkaline chemical solutions, to dry etching technology using etching gas in place of chemical solutions. One of the reasons why dry etching technology has received attention is because of its low pollution characteristics. A demand to reduce large amounts of various chemicals used in semiconductor fabrication processes, including etching to the lowest possible level, was one motivation for the development of dry etching technology. In addition, dry etching technology possesses the compelling characteristics that processing extent is high and microprocessing is possible with such technique.

In order to fabricate the pattern of CNT film on the surface, the purified single-walled CNT is cut into short nanotube pieces using an acid. The cut CNT pieces have mainly —COOH chemical functional groups at a part of ends and sidewall of the cut tube. The properties of the CNT have been modified by chemical binding of various materials using these chemical functional groups. Further, it has been reported that the functional group of CNT was substituted for —SH group by chemical manipulation and patterned on a gold surface using microcontact printing method (Nan, X. et al., J. Colloid Interface Sci., 245:311, 2002) and that CNT was immobilized on a substrate in the shape of a multilayered film using an electrostatic method (Rouse, J. H. et al., Nano Lett., 3:59, 2003). However, the former has disadvantages of low CNT surface density and weak bonding, and the latter also has a fatal disadvantage that the patterning method for selective immobilization on the surface cannot be applied. Therefore, there is an urgent need for developing a new type of surface immobilizing method with high density.

Meanwhile, the present inventors previously developed a method for fabricating a CNT-biochip, the method comprising: depositing CNTs on a substrate with amine groups exposed by chemical bonds so as to form a high-density CNT film or pattern with chemical functional groups exposed; and either chemically bonding a bioreceptor to the CNT film or pattern, or treating the CNT surface by physical adsorption with a chemical substance for the prevention of non-specific bonding and then chemically bonding the bioreceptor to the CNT film (Korean Patent Application No. 10-2003-51140).

The prior method is shown in FIG. 1. As shown in FIG. 2, the prior method has a shortcoming in that CNTs selectively attached onto the substrate cannot be formed into perfect patterns, since some CNTs are attached to t-BOC groups, by the interaction between the hydrophobic property of the t-BOC groups chemically bonded onto the substrate for patterning and the hydrophobic property of the outer wall of CNTs. In other words, if CNT multilayer film patterns as shown in FIG. 1 are formed, various patterns as shown in FIG. 2(a)-(d) can be formed, but if the number of reactions increases in order to obtain a high-density surface, some CNTs are attached onto non-selected regions as shown in FIG. 2(e), thereby limiting the application of the prior method.

Accordingly, the present inventors have conducted extensive studies to solve the above-mentioned problem, and consequently found that a method which comprises depositing CNT layers on a substrate so as to form a CNT multilayer film, patterning the CNT multilayer film by photolithography, and selectively removing the CNT multilayer film by dry etching, and preferably reactive ion etching, results in forming clear CNT multilayer film patterns where CNTs are attached only at selected regions. On the basis of this finding, the present invention has been perfected.

### SUMMARY OF THE INVENTION

The present invention relates to a method for forming clear CNT multilayer patterns where CNTs are attached only at selected regions.

Also, the present invention relates to a method for fabricating CNT multilayer patterns where a variety of chemical functional groups are exposed, the method comprising thermally treating the CNT multilayer film pattern obtained in the former method so as to obtain CNT multilayer film patterns having no defect site, and then physically attaching either surfactants or chemical substances having sites capable of π-stacking, to the CNT multilayer film patterns having no defect site.

Other aspects, features and advantages of the invention will be more fully apparent from the ensuing disclosure and appended claims.

### BRIEF DESCRIPTION OF THE DRAWINGS

FIG. 1 shows a process of forming CNT multilayer film patterns according to the prior art.

FIG. 2 shows SEM photographs of CNT multilayer film patterns fabricated according to the prior art.

FIG. 3 is a schematic diagram showing a process of fabricating CNT multilayer film patterns by depositing CNTs having exposed carboxyl groups onto a substrate having exposed amine groups by amide linkage.

FIG. 4 shows a process of fabricating CNT multilayer film patterns from the CNT multilayer film by photolithography and dry etching.

FIG. 5 shows photographs of the optical microscope image of the surface of the CNT multilayer film having photoresist patterns formed by photolithography in the fabrication process of the CNT multilayer film patterns.

FIG. 6 shows photographs of an optical microscope image after conducting dry etching using the photoresist patterns formed by photolithography in the fabrication process of the CNT multilayer film patterns. FIG. 6(a) shows the results of reactive ion etching conducted for 75 seconds, and FIG. 6(b) shows the results of reactive ion etching conducted for 90 seconds.

FIG. 7 shows photographs of the optical microscope image of CNT multilayer film patterns fabricated by removing the photoresist patterns after conducting the reactive ion etching in the fabrication process of the CNT multilayer film patterns. FIG. 7(a) shows results obtained by removing the photoresist patterns after conducting the reactive ion etching for 60 seconds, FIG. 7(b) shows results obtained by removing the photoresist patterns after conducting the reactive ion etching for 75 seconds, and FIG. 7(c) shows results obtained by removing the photoresist patterns after conducting the reactive ion etching for 90 seconds.

FIG. 8(a) shows a photograph showing a scanning electron microscope image after conducting the reactive ion etching for 45 seconds in the fabrication process of the CNT multilayer film patterns. FIG. 8(b) is an enlarged photograph of a surface subjected to the reactive ion etching.

FIG. 9(a) is a photograph showing the scanning electron microscope image of CNT multilayer film patterns obtained by removing photoresist after conducting the reactive ion etching for 60 seconds, and FIG. 9(b) is a photograph showing the scanning electron microscope image of a boundary between a surface subjected to the reactive ion etching and a surface subjected to no reactive ion etching.

FIG. 10 shows a method for fabricating CNT multilayer film patterns where various chemical functional groups are exposed, the method comprising physically attaching either surfactants or chemical substances having sites capable of π-stacking, to CNT multilayer film patterns from which defect sites had been removed by thermal treatment.

### DETAILED DESCRIPTION OF THE INVENTION AND PREFERRED EMBODIMENT THEREOF

In one embodiment, the present invention provides a method for fabricating CNT multilayer film patterns having carboxyl groups exposed to the surface, the method comprising the steps of: (a) reacting a substrate having amine groups exposed to the surface with CNTs having carboxyl groups exposed to the surface so as to form a CNT monolayer on the substrate surface by the amide linkage between the amine groups and the carboxyl groups; (b) reacting the CNT monolayer with a diamine organic compound so as to form an organic amine layer on the CNT monolayer, and reacting the organic amine layer with CNTs having exposed carboxyl groups so as to deposit a CNT layer on the organic amine layer; (c) repeating the step (b) n times so as to deposit the CNT layer and the organic amine layer on top of each other alternately n times, thereby forming a CNT multilayer film having exposed carboxyl groups; (d) coating photoresist (PR) on the CNT multilayer film; (e) exposing the coated PR to light using a photomask and then developing the exposed PR, so as to form PR patterns on the CNT multilayer film; and (f) subjecting the CNT multilayer film to dry etching using the PR patterns as masks and then removing the PR patterns.

In another embodiment, the present invention provides CNT multilayer film patterns having carboxyl groups exposed to the surface, which are fabricated by the above method.

In still another embodiment, the present invention provides a method for fabricating CNT multilayer film patterns where chemical functional groups selected from the group consisting of amine, aldehyde, hydroxyl, thiol groups and halogen groups are exposed on the surface, the method comprising the steps of: (a) reacting a substrate having amine groups exposed to the surface with CNTs having carboxyl groups exposed to the surface so as to from a CNT monolayer on the substrate surface by the amide linkage between the amine groups and the carboxyl groups; (b) reacting the CNT monolayer with a diamine organic compound so as to from an organic amine layer on the CNT monolayer, and reacting the organic amine layer with CNTs having exposed carboxyl groups so as to deposit a CNT layer on the organic amine layer; (c) repeating the step (b) n times so as to deposit the CNT layer and the organic amine layer on top of each other alternately n times, thereby forming a high-density CNT film having exposed carboxyl groups; (d) modifying the high-density CNT film having carboxyl groups exposed with a chemical substance having not only functional groups bonding with the carboxyl groups but also chemical functional groups selected from the group consisting of amine, aldehyde, hydroxyl and thiol and halogen groups; (e) coating PR on the modified CNT multilayer film; (f) exposing the coated PR to light using a photomask, and then developing the exposed PR so as to form PR patterns on the CNT multilayer film; and (g) subjecting the CNT multilayer film to dry etching using the PR patterns as masks, and then removing the PR patterns.

In still another embodiment, the present invention provides a method for fabricating CNT multilayer film patterns where chemical functional groups selected from the group consisting of amine, aldehyde, hydroxyl, thiol and halogen groups are exposed to the surface, the method comprising the steps of: (a) reacting a substrate having amine groups exposed to the surface with CNTs having carboxyl groups exposed to the surface so as to form a CNT monolayer on the substrate surface by the amide linkage between the amine groups and the carboxyl groups; (b) reacting the CNT monolayer with a diamine organic compound to form an organic amine layer on the CNT monolayer, and reacting the organic amine layer with CNTs having exposed carboxyl groups so as to deposit a CNT layer on the organic amine layer; (c) repeating the step (b) n times so as to deposit the CNT layer and the organic amine layer on top of each other alternately n times, thereby forming a high-density CNT multilayer film having exposed carboxyl groups; (d) coating PR on the CNT multilayer film; (e) exposing the coated PR to light using a photomask, and then developing the exposed PR, so as to form PR patterns on the CNT multilayer film; (f) subjecting the CNT multilayer film to dry etching using the PR patterns as masks, and then removing the PR patterns, so as to form CNT multilayer film patterns having carboxyl groups exposed to the surface; and (g) modifying the CNT multilayer film patterns having carboxyl groups exposed with a chemical substance having not only functional groups bonding with the carboxyl groups but also chemical functional groups selected from the group consisting of amine, aldehyde, hydroxyl, thiol and halogen groups.

In another embodiment, the present invention provides CNT multilayer film patterns where chemical functional groups selected from the group consisting of amine, aldehyde, hydroxyl, thiol and halogen groups are exposed to the surface, in which the CNT multilayer film patterns are fabricated by the above method.

In yet another embodiment, the present invention provides a method for fabricating CNT multilayer film patterns where chemical functional groups selected from the group consisting of carboxyl, amine, aldehyde, hydroxyl, thiol and halogen groups are exposed, the method comprising the steps of: (a) thermally treating the CNT multilayer film patterns having exposed carboxyl groups, so as to obtain CNT multilayer film pattern having no defect site on the surface; and (b) physically attaching surfactants or chemical substances to the CNT multilayer film patterns obtained in the step (a), the surfactants having not only chemical functional groups selected from the group consisting of carboxyl, amine, aldehyde, hydroxyl, thiol and halogen groups but also functional groups capable of binding to the CNT multilayer film patterns by physical interaction, the chemical substances having not only chemical functional groups selected from the group consisting of carboxyl, amine, aldehyde, hydroxyl, thiol and halogen groups but also sites capable of π-stacking.

In another further embodiment, the present invention provides a method for fabricating CNT multilayer film patterns where chemical functional groups selected from the group consisting of carboxyl, amine, aldehyde, hydroxyl, thiol and halogen groups are exposed, the method comprising the steps of: (a) thermally treating the CNT multilayer film patterns where chemical functional groups selected from the group consisting of amine, aldehyde, hydroxyl, thiol and halogen groups are exposed, thereby obtaining CNT multilayer film patterns having no defect site on the surface; and (b) physically attaching surfactants or chemical substances to the CNT multilayer film patterns obtained in the step (a), the surfactants having not only chemical functional groups selected from the group consisting of carboxyl, amine, aldehyde, hydroxyl, thiol and halogen groups but also functional groups capable of binding to the CNT multilayer film patterns by physical interaction, the chemical substances having not only chemical functional groups selected from the group consisting of carboxyl, amine, aldehyde, hydroxyl, thiol and halogen groups but also sites capable of π-stacking.

In the present invention, the thermal treatment is preferably performed either at temperature in a range of from 400 to 500° C. under ambient pressure or at temperature in a range of from 700 to 900° C. under vacuum conditions.

In the present invention, the surfactants having not only chemical functional groups selected from the group consisting of carboxyl, amine, aldehyde, hydroxyl, thiol and halogen groups but also functional groups capable of binding to the CNT multilayer film patterns by physical interaction are preferably R₁—NH₂, R₂—SH, R₃—OH, R₄—CHO or R₅—X wherein R₁, R₂, R₃, R₄ and R₅ each independently represents a hydrophobic organic group, such as an alkyl, alkyl-aryl, or alkyl-heterocyclic group, and X is a halogen atom or succinimidyl ester. Furthermore, the surfactants include anionic, cationic, amphoteric and non-ionic surfactants.

The chemical substances having not only chemical functional groups selected from the group consisting of carboxyl, amine, aldehyde, hydroxyl, thiol and halogen groups but also sites capable of π-stacking are preferably pyrene-R₁—COOH, pyrene-R₁—NH₂, pyrene-R₂—SH, pyrene-R₃—OH, pyrene-R₄—CHO or pyrene-R₅—X wherein R₁, R₂, R₃, R₄ and R₅ each independently represents a C₁₋₂₀ saturated or unsaturated hydrocarbon or aromatic organic group, and X is a halogen atom or succinimidyl ester. In addition to the pyrene-containing substances capable of π-stacking, it is also within the scope of the present invention to use other chemicals showing a phenomenon where electrons are delocalized by the overlapping of π-bonds between aromatic side chains, which is the principle of π-stacking.

In the present invention, the dry etching is preferably performed by using one or more gases selected from the group consisting of CF₄, SF₆, Cl₂, SiCl₄, HBr, CHF₃, C₂F₆, BCl₃, CCl₄, O₂ and O₃. Also, the dry etching is preferably performed by an etching method selected from the group consisting of reactive ion etching (RIE), magnetron reactive ion etching, sputter etching, ion beam etching (ion milling), cylindrical plasma etching, helicon wave plasma etching, microwave plasma etching, inductively coupled plasma (ICP) etching, electron cyclotron resonance (ECR) plasma etching, focused ion beam (FIB) etching, gas cluster ion beam (GCIB) etching, and chemical mechanical polishing (CMP).

According to the present invention, the chemicals having both the functional group capable of binding to carboxyl group and the chemical functional group selected from the group consisting of amine group, aldehyde group, hydroxyl group, thiol group and halogen preferably include H₂N—R₁—NH₂, H₂N—R₂—CHO, H₂N—R₃—OH, H₂N—R₄—SH, or H₂N—R₅—X in which R₁, R₂, R₃, R₄ and R₅ are independently a C₁₋₂₀ saturated hydrocarbon, unsaturated hydrocarbon or aromatic organic group and X is halogen element.

In the present invention, after the desired CNT multilayer patterns are formed by lithography, conducting wires may be connected to the CNT patterns either by thermal deposition, e-beam deposition or sputtering, or by electroplating due to good resistance of PR and ER to an acidic or basic aqueous solution in order to apply electric charge to each of the CNT multilayer patterns.

### EXAMPLES

The present invention will hereinafter be described in further detail by examples. However, it is to be understood that these examples can be modified into other various forms, and the scope of the present invention is not intended to be limited to such examples. Such examples are given to more fully describe the present invention for a person skilled in the art.

### Example 1

### Preparation of CNT Having Exposed Carboxyl Groups

The CNT, which can be used in the present invention, is not particularly limited and can be commercially available products or prepared by a conventional method. Pure CNT should be carboxylated at its surface and/or both ends to be used in the present invention.

The purified CNT was cut in a sonicator containing an oxidizing acid (a mixture of nitric acid and sulfuric acid) for 24 hours, in order to obtain CNTs having exposed carboxyl groups and diluted with distilled water, and then centrifuged. Supernatant was removed and washed with distilled water several times, and then the obtained CNT suspension was filtered through a 0.1 μm filter and dried followed by suspending CNTs having exposed carboxyl groups into distilled water or organic solvent.

### Example 2

### Preparation of a Substrate Having Exposed Amine Group

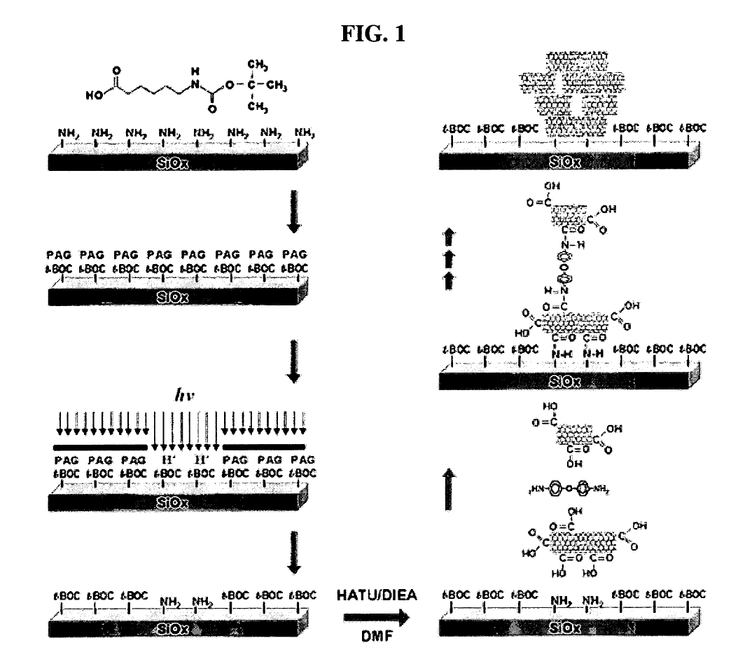

In the present invention, the substrate having exposed amine groups was prepared by modification with aminealkyloxysilane of a substrate such as silicon, glass, melted silica, plastics, PDMS (polydimethylsiloxane), and the like. However, commercially available substrates, which have been surface-treated with amine, can also be used. FIG. 1 shows a process of forming CNT multilayer film patterns according to the prior art.

### Example 3

### Preparation of a High Density CNT Film

The method for preparing a high density CNT film was described in prior Korean Patent Application No. 10-2003-0051826.

(1) Preparation of High Density CNT Film Having Carboxyl Groups Exposed on its Surface

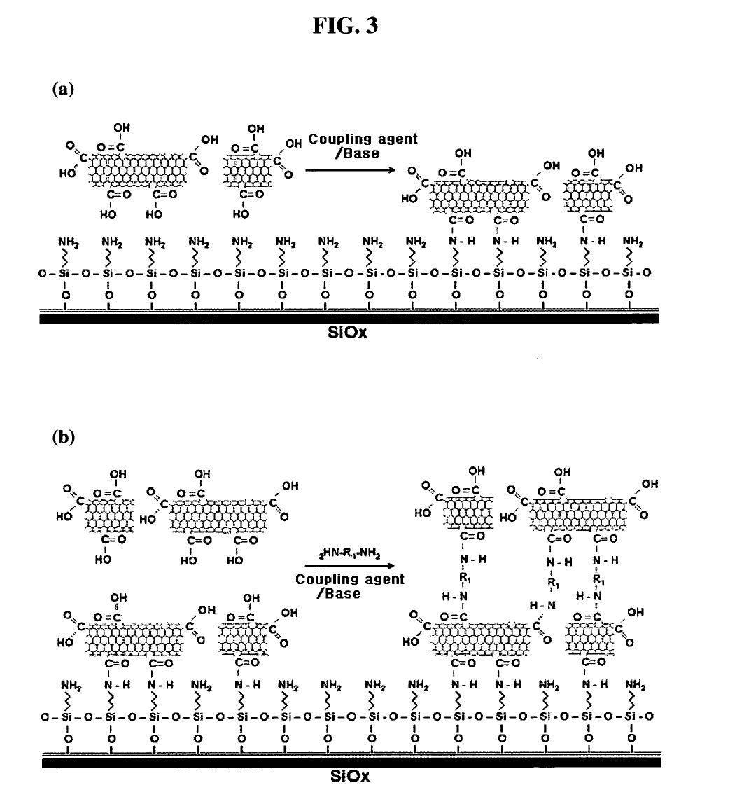

The CNT having exposed carboxyl groups, prepared in Example 1, was reacted with the substrate having exposed amine groups, prepared in Example 2, to form a CNT single layer on the substrate by amide bond formation between the carboxyl group and the amine group (FIG. 3(a)).

Next, the CNT attached to the substrate by amide bond was reacted with a diamine type organic compound having double amine functional groups while CNT having exposed carboxyl groups was reacted with amine groups at the other side of the diamine type organic compound to deposit another CNT layer by the formation of amide bonds (FIG. 3(b)).

Next, the chemical reaction between the CNT having exposed carboxyl groups and the diamine type organic compound was repeated to prepare a high density CNT film comprising the CNT layer and the organic amine layer laminated alternately n times and having carboxyl groups exposed on its surface (FIG. 3(c)).

The diamine type organic compound which can be used in the present invention includes compounds having a formula of HN₂—R₁—NH₂, in which R₁ is selected from among C₁₋₂₀ saturated hydrocarbons, unsaturated hydrocarbons and aromatic organic groups.

To accelerate the formation of the above amide bond, HAMDU (O-(7-azabenzotriazol-1-yl)-1,3-dimethyl-1,3-dimethyleneuronium hexafluorophosphate), DCC(1,3-dicyclohexyl carbodiimide), HAPyU(O-(7-azabenzotriazol-1-yl)-1,1:3,3 -bis(tetramethylene)uronium hexafluorophosphate), HATU(O-(7-azabenzotriazol-1-yl)-1,1:3,3-tetra methyluronium hexafluorophosphate), HBMDU(O-(benzotriazol-1-yl)-1,3-dimethyl-1,3-dimethyleneuronium hexafluorophosphate), or HBTU(O-(benzotriazol-1-yl)-1,1,3,3-tetramethyluronium hexafluorophosphate) is preferably used as a coupling agent, and DIEA(diisopropylethylamine), TMP(2,4,6-trimethylpyridine), or NMI(N-methylimidazole) is preferably used as a base.

Also, in the case of using water as solvent, EDC(1-ethyl-3-(3-dimethylamini-propyl) carbodiimide hydrochloride) is preferably used as a coupling agent, and NHS(N-hydroxysuccinimide) or NHSS(N-hydroxysulfosuccinimide) is preferably used as a co-coupling agent (base).

In this Example, HATU was used as a coupling agent and DIEA was used as a base. The coupling agent participates in the formation of the amide bond (—CONH—) between the —COOH functional group and the —NH₂ functional group, and the base agent acts to increase the efficiency when the coupling agent forms the amide bond.

(2) Modification of the High Density CNT Film Having Exposed Carboxyl Groups

The CNT film having exposed carboxyl groups can be modified by chemicals having both a chemical functional group (amine group, hydroxyl group, etc.) capable of reacting with the carboxyl group and a chemical functional group (amine group, hydroxyl group, thiol group, aldehyde group, etc.) capable of binding to a functional group of a target bio-receptor. The chemicals that can be used in such modification include H₂N—R₁—NH₂, H₂N—R₂—CHO, H₂N—R₃—OH, H₂N—R₄—SH, H₂N—R₅—X and the like, in which R₁, R₂, R₃, R₄ and R₅ are independently a C₁₋₂₀ saturated hydrocarbon, unsaturated hydrocarbon or aromatic organic group and X is halogen element.

### Example 4

### Fabrication of CNT Multilayer Patterns by Photolithography

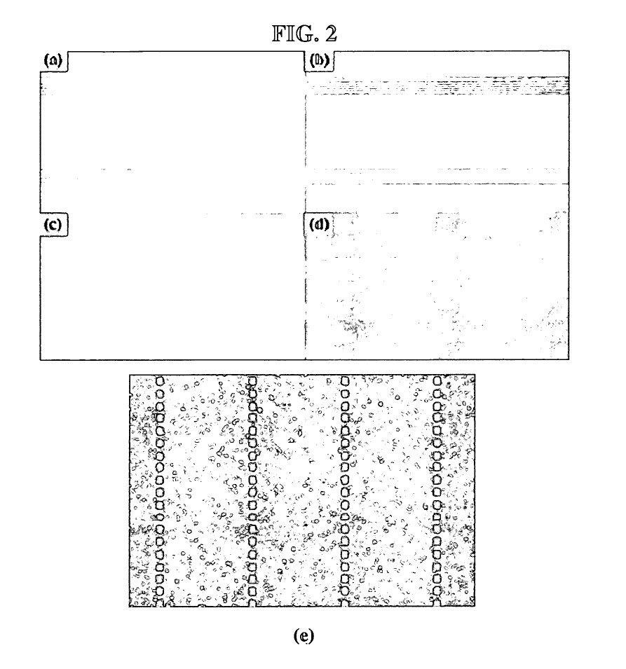

The prior method as shown in FIG. 1 has a shortcoming in that CNTs selectively attached onto a substrate cannot be formed into perfect patterns, since some CNTs are attached to t-BOC groups by the interaction between the hydrophobic property of the t-BOC groups chemically bonded onto the substrate surface for patterning and the hydrophobic property of the outer wall of CNTs (see FIG. 2). In order to solve the above problem occurring in the prior method, in this Example, a CNT multilayer film deposited on a substrate was patterned by photolithography and dry etching, specifically reactive ion etching.

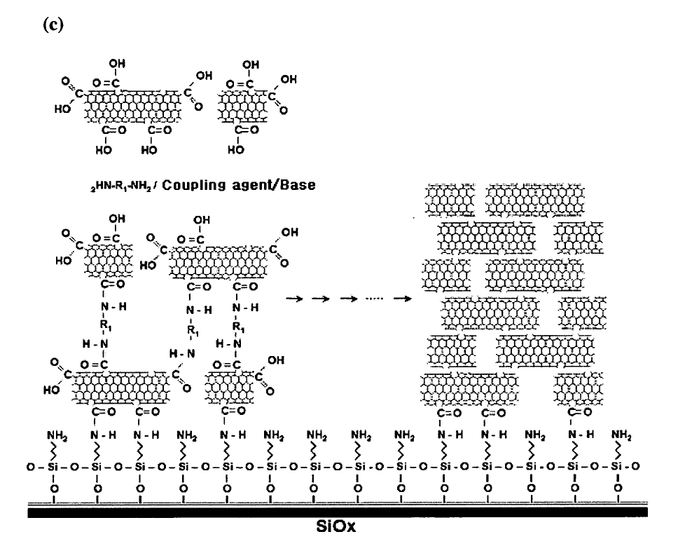

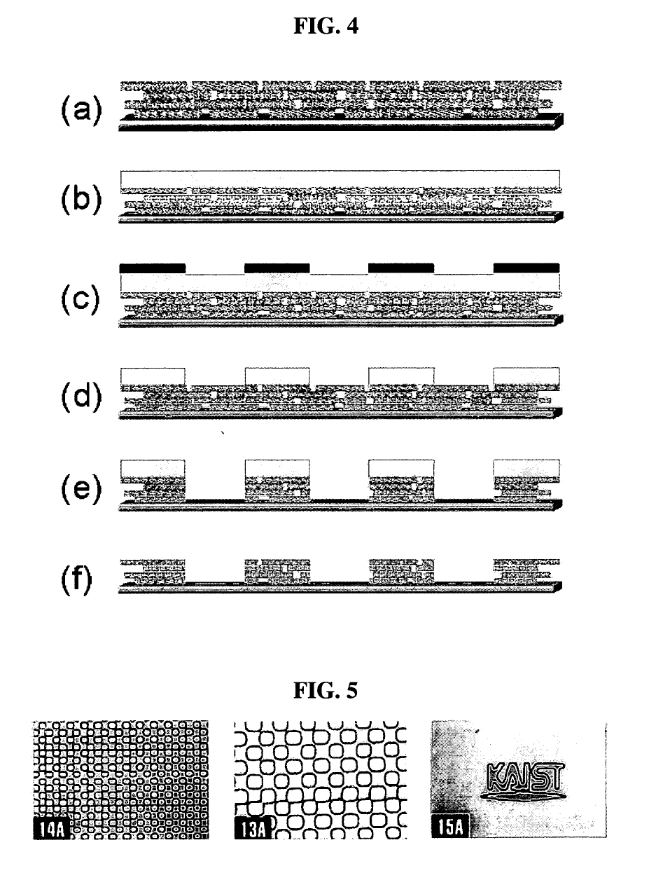

Photoresist (PR) was coated on the CNT multilayer film formed in Example 3 by a conventional method (FIG. 4(b)), and then exposed to light by irradiation with UV light using a photomask having the desired patterns formed thereon (FIG. 4(c)). The light-transmitted portion and light-blocked portion of PR are polymerized or degraded, selectively, and the patterns of the photomask are transferred onto PR. Examples of PR which can be used include positive PR and negative PR. The positive PR is a polymer which is degraded by UV light, and the negative PR is a polymer which forms a strong bond by UV light. The kind of PR used can vary depending on the pattern size, and if the width of pattern lines is reduced to the nanometer size, e-beam resist (ER) is used. In this Example, AZ9260, among AZ series PRs which are typical positive PRs, was used. AZ9260 was spin-coated at 2400 rpm for 60 seconds, cured by baking in an oven at 90° C. for 2 minutes and 45 seconds, and then exposed to light with an UV-exposure system (MA6, Karl Suss) for 100 seconds. In this Example, all kinds of photomasks, such as quartz and soda lime substrates which are widely used in semiconductor processes and can transmit UV light, may be used.

Meanwhile, if AZ 5214 which is PR capable of forming both positive and negative patterns is used, it is spin-coated at 4000 rpm for 30 seconds, and cured on a hot plate at 90° C. for 3 minutes. In this case, positive patterns made of AZ5214 are formed by light exposure for 8-10 seconds, and phase-shift patterns are formed by light exposure for 1 second, baking at 120° C. for 60 seconds, followed by light exposure for 15 seconds. Exposure methods that can be used in the exposure step include UV exposure using a photomask, exposure using steppers and a scanning projection system, electron beam exposure using an e-beam writer, and X-ray exposure using X-ray systems. A preferred exposure method can be selected depending on the size and shape of the patterns.

Next, the photoresist was developed to form PR patterns on the CNT film (FIG. 4(d)). When the CNT film having the photoresist coated thereon is immersed in a developer, only PR portions where a polymer bond had been broken are melted out and the underlying CNT layer is exposed. When AZ9260 was used as PR, AZ400K was then used as a developer. After about 1 minute of immersion in the developer, the CNT film was taken out and rinsed with distilled water. Under observation with an optical microscope, the development step was repeated until the PR portions where a polymer bond had been broken were completely dissolved. When PR is AZ5214, AZ340 is then used as a developer. However, it was used after dilution with water in order to form precise patterns by increasing development time. The development time is much influenced by operation conditions, such as temperature and humidity, but when the developer was diluted at a developer/water ratio of 1/5 with water, the desired patterns could be obtained at a development time of 1 minute and 30 seconds.

Thereafter, dry etching, preferably reactive ion etching, was performed using the PR patterns as masks (FIG. 4(e)). In the dry etching step, the material to be etched is etched in a series of process consisting of reactive gas→the production of reactive species (radicals and ions)→the scattering of reactive species→reaction with the material to be etched→the production and escape of volatile reaction products→exhaust. Examples of the etching gas which can be used in the etching step include CF₄, SF₆, Cl₂, SiCl₄, HBr, CHF₃, C₂F₆, BCl₃, CCl₄, O₂, O₃ and the like. In the present invention, CF₄ gas was used and etching was conducted on each sample for 30-300 seconds, and particularly for 45 seconds, 60 seconds, 75 seconds and 90 seconds. The etching gas is decomposed by electron impact in plasma so as to produce F radicals. The F radicals react with the material to be etched so as to form volatile substances, which escape, thereby performing the etching of the CNT film. In the etching step, the patterned PR is etched out in place of the CNT film, so that the underlying CNT multilayer film can be protected. This characteristic is applied to the present invention. Namely, if the reactive ion etching process is applied, an exposed portion of the CNT multilayer film is etched but a portion of the CNT multilayer film which has been covered with PR, remains.

Finally, the remaining PR was completely removed, thereby forming CNT multilayer film patterns (FIG. 4(f)). In this step, ketone solvent, such as acetone, is used to remove PR, and the substrate having the CNT multilayer film patterns formed thereon was immersed in acetone for 2-24 hours in order to remove PR. The remaining resist was removed using oxygen plasma.

The PR coating, light exposure (UV irradiation), development, dry etching, and PR removal steps, etc., used in the present invention, were carried out under the same conditions as the ones in the conventional photolithographic method used in semiconductor processes.

FIG. 5 shows photographs of an optical microscope image obtained after forming photoresist patterns by photolithography but before conducting the reactive ion etching, in the fabrication process of the CNT multilayer film patterns. As shown in FIG. 5, it suggests that the patterns of the photomask were transferred onto PR covering the CNT multilayer film, and the PR patterns could function as masks for the CNT multilayer film in the subsequent step.

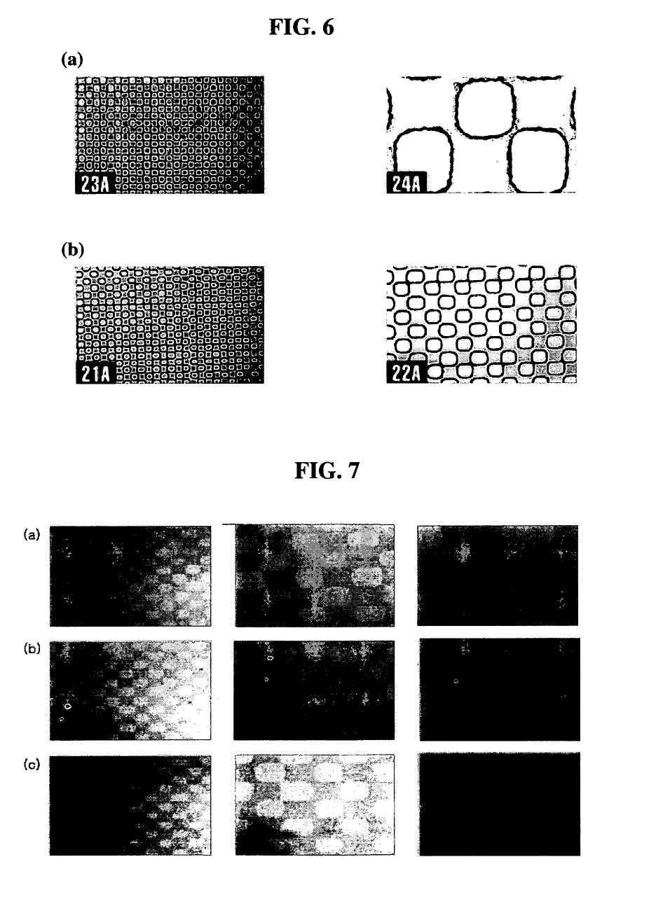

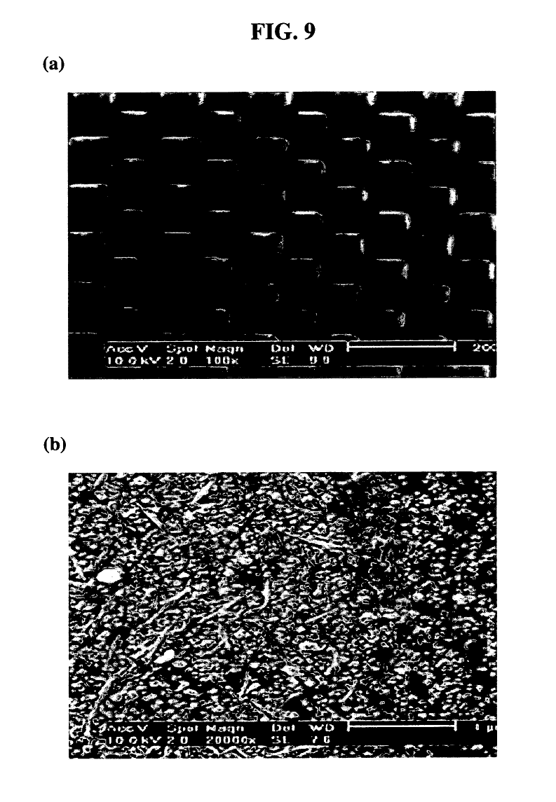

FIG. 6 shows photographs of an optical microscope image obtained after conducting the reactive ion etching in the fabrication process of CNT multilayer film patterns. In FIG. 6, (a) shows results obtained after conducting the reactive ion etching for 75 seconds, and (b) shows results obtained after conducting the reactive ion etching for 90 seconds. The optical microscope image in FIG. 6 could not be distinguished from FIG. 5 which is the optical microscope image of FIG. 5 before conducting the reactive ion etching. However, as evident from FIG. 9 showing a scanning electron microscope image, the exposed portions of the CNT multilayer film were completely removed after reactive ion etching, so that the desired patterns were formed.

FIG. 7 shows photographs of the optical microscope image of the CNT multilayer film patterns fabricated according to this Example. The magnifications of the image increase toward the right side in FIG. 7. In FIG. 7, (a) shows results obtained after conducting the reactive ion etching for 60 seconds, (b) shows results obtained after conducting the reactive ion etching for 75 seconds, and (c) shows results obtained after conducting the reactive ion etching for 90 seconds. As shown in FIG. 7, the portions of the CNT multilayer film, which had been covered with PR, remained the same as the PR patterns, after the PR patterns had been removed.

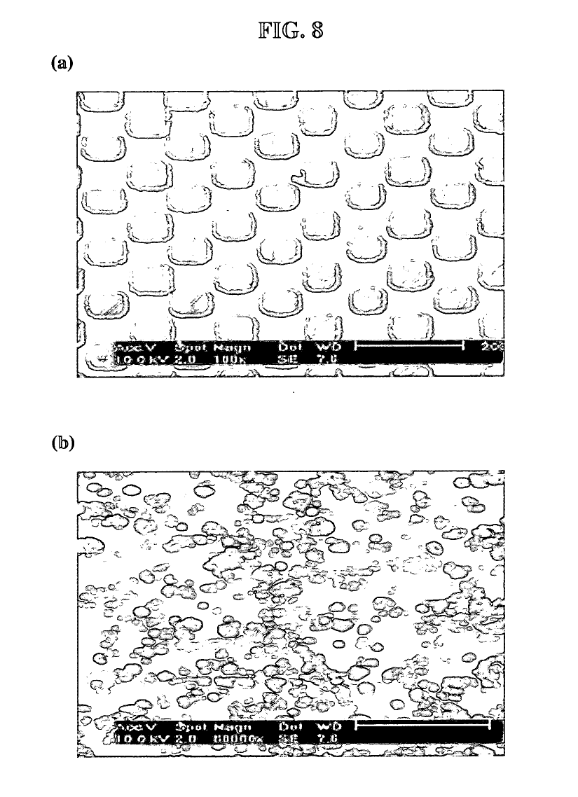

FIG. 8(a) shows a photograph of a scanning electron microscope image obtained after conducting the reactive ion etching for 45 seconds in the fabrication process of the CNT multilayer film patterns. FIG. 8(b) is an enlarged photograph of a surface subjected to the reactive ion etching. As shown in FIG. 8, some CNTs remained on the surface since the reactive ion etching was performed for a short time.

FIG. 9(a) shows a photograph of the scanning electron microscope image of the CNT multilayer film patterns fabricated by conducting the reactive ion etching for 60 seconds followed by the removal of the PR patterns. FIG. 9(b) is a scanning electron microscope photograph showing the high-magnification image of a boundary between a surface of the multilayer film, subjected to the reactive ion etching, and a surface subjected to no reactive ion etching (a surface covered with PR). As shown in FIG. 9, it could be found that, in the CNT multilayer film patterns, portions to which CNT had been attached and portions from CNT had been removed, were clear.

### Example 5

### Fabrication of CNT Multilayer Film Patterns to which Functional Groups have been physically attached

The CNT multilayer film patterns fabricated by the method of Example 4 were thermally treated either at 400-500° C. under ambient pressure or at 700-900° C. under vacuum, so as to obtain CNT multilayer film patterns having no defect site on the surface. Since the sidewall of CNTs present on the CNT multilayer film patterns having no defect site is hydrophobic in nature, surfactants having hydrophobic organic groups can physically bind to the CNT multilayer film patterns by hydrophobic interaction. Thus, surfactants (R₁—NH₂, R₂—SH, R₃—OH, R₄—CHO or R₅—X) having not only hydrophobic groups capable of binding to the CNT multilayer film patterns by hydrophobic interaction but also chemical functional groups selected from the group consisting of carboxyl, amine, aldehyde, hydroxyl, thiol and halogen groups, can bind to the CNT multilayer film patterns having no defect site. Here, R₁, R₂, R₃, R₄ and R₅ each independently represents a hydrophobic organic group, such as an alkyl, alkyl-aryl, or alkyl-heterocyclic group, and X is a halogen atom or succinimidyl ester. Also, the surfactants include anionic, cationic, amphiprotic and non-ionic surfactants.

Furthermore, chemical substances having not only a chemical functional group selected from the group consisting of carboxyl, amine, aldehyde, hydroxy, thiol and halogen groups, but also sites capable of π-stacking, may be bonded to the CNT multilayer film patterns. Examples of such chemical substances include pyrene-R₁—NH₂, pyrene-R₂—SH, pyrene-R₃—OH, pyrene-R₄—CHO, and pyrene-R₅—X, wherein R₁, R₂, R₃, R₄ and R₅ each independently represents a C₁₋₂₀ saturated or unsaturated hydrocarbon or aromatic organic group, and X is a halogen atom or succinimidyl ester.

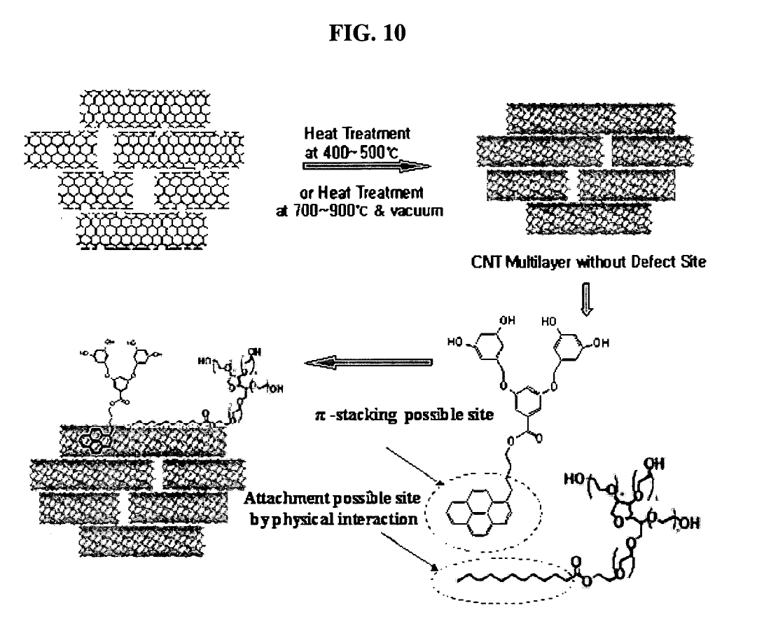

In this Example, either a surfactant having a hydrophobic organic group, such as Tween-20, Pluronic P103 or Triton X-100, or a compound of the following formula 1 or 2, which has a site capable of π-stacking, was dissolved in DMF or THF solvent, and then the CNT multilayer film patterns were dipped in the solution for 1-24 hours so as to physically attach the compound to the CNT multilayer film. This resulted in the fabrication of CNT multilayer film patterns where chemical functional groups selected from the group consisting of carboxyl, amine, aldehyde, hydroxyl, thiol and halogen groups are exposed (FIG. 10).

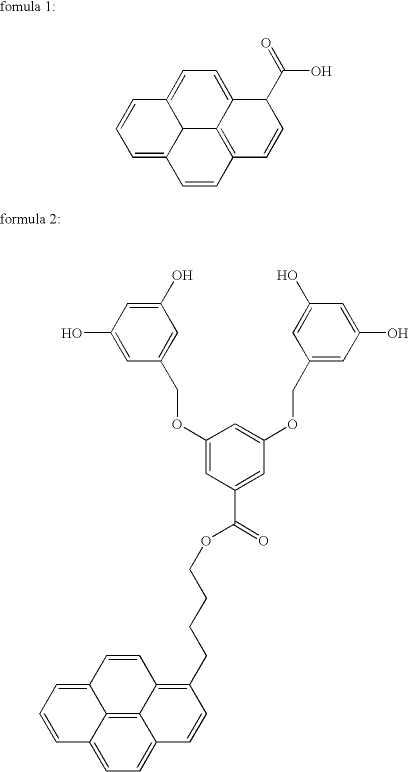

Alternatively, the chemical substances may also be physically attached to the CNT multilayer film patterns by chemical vapor deposition or thermal vapor deposition, so as to fabricate CNT multilayer film patterns where chemical functional groups selected from the group consisting of carboxyl, amine, aldehyde, hydroxyl, thiol and halogen groups are exposed.

In this Example, although only the hydroxyl group has been illustrated as a chemical functional group, compounds having other chemical functional groups may also be physically attached. Such CNT multilayer film patterns, which chemical functional groups are attached thereto and exposed to the surface, will be useful for the fabrication of biosensors.

As described above in detail, the present invention provides the method for forming the CNT multilayer film patterns, which comprises repeatedly attaching CNTs having exposed carboxyl groups onto the substrate having exposed amine groups, by amide linkage, so as to obtain a CNT multilayer film with high density, and then forming CNT multilayer film patterns from the CNT multilayer film by photolithography and dry etching.

The present invention makes it possible to form clear CNT multilayer film patterns where CNTs are attached only at selected regions. Thus, the present invention provides a solution to solve the problem of the prior art where CNTs are attached also at non-selected regions.

Furthermore, the present invention provides the method for fabricating the CNT multilayer film patterns where various chemical functional groups are exposed, the method comprising physically attaching either surfactants or chemical substances having sites capable of π-stacking, to the CNT multilayer film patterns from which defect sites had been removed. Such CNT multilayer film patterns in which chemical functional groups are physically attached thereto and exposed to the surface, will be useful for the fabrication of biosensors.

While the present invention has been described with reference to the particular illustrative embodiment, it is not to be restricted by the embodiment but only by the appended claims. It is to be appreciated that those skilled in the art can change or modify the embodiment without departing from the scope and spirit of the present invention.

1. A method for fabricating CNT multilayer film patterns having carboxyl groups exposed to the surface, the method comprising the steps of:
(a) reacting a substrate having amine groups exposed to the surface with CNTs having carboxyl groups exposed to the surface so as to form a CNT monolayer on the substrate surface by amide linkage between the amine groups and the carboxyl groups;
(b) reacting the CNT monolayer with a diamine organic compound so as to form an organic amine layer on the CNT monolayer, and reacting the organic amine layer with CNTs having exposed carboxyl groups so as to deposit a CNT layer on the organic amine layer;
(c) repeating step (b) n times so as to deposit the CNT layer and the organic amine layer on top of each other alternately n times, thereby forming a CNT multilayer film having exposed carboxyl groups;
(d) coating photoresist (PR) on the CNT multilayer film;
(e) exposing the coated PR to light using a photomask and then developing the exposed PR, so as to form PR patterns on the CNT multilayer film; and
(f) subjecting the CNT multilayer film to dry etching using the PR patterns as masks and then removing the PR patterns.

2. The method for fabricating CNT multilayer film patterns according to claim 1, wherein the dry etching is performed using one or more gases selected from the group consisting of CF₄, SF₆, Cl₂, SiCl₄, HBr, CHF₃, C₂F₆, BCl₃, CCl₄, O₂ and O₃.

3. The method for fabricating CNT multilayer film patterns according to claim 1, wherein the dry etching is performed by an etching method selected from the group consisting of reactive ion etching (RIE), magnetron reactive ion etching, sputter etching, ion beam etching (ion milling), cylindrical plasma etching, helicon wave plasma etching, microwave plasma etching, inductively coupled plasma (ICP) etching, electron cyclotron resonance (ECR) plasma etching, focused ion beam (FIB) etching, gas cluster ion beam (GCIB) etching, and chemical mechanical polishing (CMP).

4. The method for fabricating CNT multilayer film patterns according to claim 1, wherein the dry etching is performed by reactive ion etching (RIE)

5. A method for fabricating CNT multilayer film patterns where chemical functional groups selected from the group consisting of amine, aldehyde, hydroxyl, thiol groups and halogen groups are exposed on the surface, the method comprising the steps of:
(a) reacting a substrate having amine groups exposed to the surface with CNTs having carboxyl groups exposed to the surface so as to form a CNT monolayer on the substrate surface by amide linkage between the amine groups and the carboxyl groups;
(b) reacting the CNT monolayer with a diamine organic compound so as to form an organic amine layer on the CNT monolayer, and reacting the organic amine layer with CNTs having exposed carboxyl groups so as to deposit a CNT layer on the organic amine layer;
(c) repeating step (b) n times so as to deposit the CNT layer and the organic amine layer on top of each other alternately n times, thereby forming a high-density CNT film having exposed carboxyl groups;
(d) modifying the high-density CNT film having carboxyl groups exposed with a chemical substance having not only functional groups bonding with the carboxyl groups but also chemical functional groups selected from the group consisting of amine, aldehyde, hydroxyl and thiol and halogen groups;
(e) coating PR on the modified CNT multilayer film;
(f) exposing the coated PR to light using a photomask, and then developing the exposed PR so as to form PR patterns on the CNT multilayer film; and
(g) subjecting the CNT multilayer film to dry etching using the PR patterns as masks, and then removing the PR patterns.

6. A method for fabricating CNT multilayer film patterns where chemical functional groups selected from the group consisting of amine, aldehyde, hydroxyl, thiol and halogen groups are exposed to the surface, the method comprising the steps of:
(a) reacting a substrate having amine groups exposed to the surface with CNTs having carboxyl groups exposed to the surface so as to form a CNT monolayer on the substrate surface by amide linkage between the amine groups and the carboxyl groups;
(b) reacting the CNT monolayer with a diamine organic compound to form an organic amine layer on the CNT monolayer, and reacting the organic amine layer with CNTs having exposed carboxyl groups so as to deposit a CNT layer on the organic amine layer;
(c) repeating step (b) n times so as to deposit the CNT layer and the organic amine layer on top of each other alternately n times, thereby forming a high-density CNT multilayer film having exposed carboxyl groups;
(d) coating PR on the CNT multilayer film;
(e) exposing the coated PR to light using a photomask, and then developing the exposed PR, so as to form PR patterns on the CNT multilayer film;
(f) subjecting the CNT multilayer film to dry etching using the PR patterns as masks, and then removing the PR patterns, so as to form CNT multilayer film patterns having carboxyl groups exposed to the surface; and
(g) modifying the CNT multilayer film patterns with a chemical substance having not only functional groups bonding with the carboxyl groups but also chemical functional groups selected from the group consisting of amine, aldehyde, hydroxyl, thiol and halogen groups.

7. The method for fabricating CNT multilayer film patterns according to claim 5 or 6, wherein the dry etching is performed by reactive ion etching (RIE)

8. The method for fabricating CNT multilayer film patterns according to claim 5 or 6, wherein the dry etching is performed using one or more gases selected from the group consisting of CF₄, SF₆, Cl₂, SiCl₄, HBr, CHF₃, C₂F₆, BCl₃, CCl₄, O₂ and O₃.

9. The method for fabricating CNT multilayer film patterns according to claim 5 or 6, wherein the chemical having both the functional group capable of binding to carboxyl group and the chemical functional group selected from the group consisting of amine group, aldehyde group, hydroxyl group, thiol group and halogen include H₂N—R₁—NH₂, H₂N—R₂—CHO, H₂N—R₃—OH, H₂N—R₄—SH, or H₂N—R₅—X in which R₁, R₂, R₃, R₄ and R₅ are independently a C₁₋₂₀ saturated hydrocarbon, unsaturated hydrocarbon or aromatic organic group and X is a halogen element.

10. A CNT multilayer film pattern having carboxyl groups exposed to the surface, fabricated by the method of claim 1.

11. A CNT multilayer film pattern where chemical functional groups selected from the group consisting of amine, aldehyde, hydroxyl, thiol and halogen groups are exposed to the surface, fabricated by the method of claim 5 or 6.

12. A method for fabricating CNT multilayer film patterns where chemical functional groups selected from the group consisting of carboxyl, amine, aldehyde, hydroxyl, thiol and halogen groups are exposed, the method comprising the steps of:
(a) thermally treating the CNT multilayer film patterns having exposed carboxyl groups according to claim 10, so as to obtain CNT multilayer film pattern having no defect site on the surface; and
(b) physically attaching surfactants or chemical substances to the CNT multilayer film patterns obtained in the step (a), the surfactants having not only chemical functional groups selected from the group consisting of carboxyl, amine, aldehyde, hydroxyl, thiol and halogen groups but also functional groups capable of binding to the CNT multilayer film patterns by physical interaction, the chemical substances having not only chemical functional groups selected from the group consisting of carboxyl, amine, aldehyde, hydroxyl, thiol and halogen groups but also sites capable of π-stacking.

13. The method for fabricating CNT multilayer film patterns according to claim 12, wherein the thermal treatment is performed either at 400-500° C. under ambient pressure or at 700-900° C. under vacuum.

14. The method for fabricating CNT multilayer film patterns according to claim 12, wherein the surfactant having not only chemical functional groups selected from the group consisting of carboxyl, amine, aldehyde, hydroxyl and halogen groups but also functional groups capable of binding to the CNT multilayer film patterns by physical interaction is R₁—NH₂, R₂—SH, R₃—OH, R₄—CHO or R₅—X wherein R₁, R₂, R₃, 4 and R₅ each independently represents a hydrophobic organic group, such as an alkyl, alkyl-aryl, or alkyl-heterocyclic group, and X is a halogen atom or succinimidyl ester.

15. The method for fabricating CNT multilayer film patterns according to claim 12, wherein the chemical substances having not only chemical functional groups selected from the group consisting of carboxyl, amine, aldehyde, hydroxyl, thiol and halogen groups but also sites capable of π-stacking are preferably pyrene-R₁—COOH, pyrene-R₁—NH₂, pyrene-R₂—SH, pyrene-R₃—OH, pyrene-R₄—CHO or pyrene-R₅—X wherein R₁, R₂, R₃, R₄ and R₅ each independently represents a C₁₋₂₀ saturated or unsaturated hydrocarbon or aromatic organic group, and X is a halogen atom or succinimidyl ester.

16. A method for fabricating CNT multilayer film patterns where chemical functional groups selected from the group consisting of carboxyl, amine, aldehyde, hydroxyl, thiol and halogen groups are exposed, the method comprising the steps of:
(a) thermally treating the CNT multilayer film patterns where chemical functional groups selected from the group consisting of amine, aldehyde, hydroxyl, thiol and halogen groups according to claim 11, thereby obtaining CNT multilayer film patterns having no defect site on the surface; and
(b) physically attaching surfactants or chemical substances to the CNT multilayer film patterns obtained in the step (a), the surfactants having not only chemical functional groups selected from the group consisting of carboxyl, amine, aldehyde, hydroxyl, thiol and halogen groups but also functional groups capable of binding to the CNT multilayer film patterns by physical interaction, the chemical substances having not only chemical functional groups selected from the group consisting of carboxyl, amine, aldehyde, hydroxyl, thiol and halogen groups but also sites capable of π-stacking.

17. The method for fabricating CNT multilayer film patterns according to claim 16, wherein the thermal treatment is performed either at temperature in a range of from 400 to 500° C. under ambient pressure, or at temperature in a range of from 700 to 900° C. under vacuum.

18. The method for fabricating CNT multilayer film patterns according to claim 16, wherein the surfactant having not only chemical functional groups selected from the group consisting of carboxyl, amine, aldehyde, hydroxyl, thiol and halogen groups but also functional groups capable of binding to the CNT multilayer film patterns by physical interaction is R₁—NH₂, R₂—SH, R₃—OH, R₄—CHO or R₅—X wherein R₁, R₂, R₃, R₄ and R₅ each independently represents a hydrophobic organic group, and X is a halogen atom or succinimidyl ester.

19. The method of claim 18, wherein R₁, R₂, R₃, R₄ and R₅ includes an alkyl, alkyl-aryl, or alkyl-heterocyclic group.

20. The method for fabricating CNT multilayer film patterns according to claim 16, wherein the chemical substances having not only chemical functional groups selected from the group consisting of carboxyl, amine, aldehyde, hydroxyl, thiol and halogen groups but also sites capable of π-stacking are pyrene-R₁—NH₂, pyrene-R₂—SH, pyrene-R₃—OH, pyrene-R₄—CHO or pyrene-R₅—X wherein R₁, R₂, R₃, R₄ and R₅ each independently represents a C₁₋₂₀ saturated or unsaturated hydrocarbon or aromatic organic group, and X is a halogen atom or succinimidyl ester.
